(19) United States
(12) Patent Application Publication
(10) Pub. No.: US 2020/0403630 A1
(43) Pub. Date: Dec. 24, 2020

(54) SELF-TRIM OF INTEGRATED CIRCUIT

(71) Applicant: Texas Instruments Incorporated, Dallas, TX (US)

(72) Inventors: Vadim Valerievich IVANOV, Tucson, AZ (US); Srinivas Kumar PULIJALA, Tucson, AZ (US); Munaf Hussain SHAIK, Tucson, AZ (US)

(21) Appl. No.: 16/446,348

(22) Filed: Jun. 19, 2019

(51) Int. Cl. H03M 1/38; H03M 1/66; H03K 5/24; H03F 3/45

(52) U.S. Cl. CPC H03M 1/38; H03M 1/66; H03F 2203/45116; H03F 3/45475; H03F 2200/129; H03K 5/24

(57) ABSTRACT

An integrated circuit (IC) includes a current source device configured to generate a bias current. The IC also includes a comparator, a circuit, a memory, and a digital-to-analog circuit (DAC). The comparator has a first input, a second input, and a comparator output. The first input receives a reference voltage, and the second input receives a voltage indicative of a bias current through the IC. The circuit is coupled to the comparator output. The circuit iteratively generates a final trim code based on an output signal from the comparator. The memory stores the final trim code. The DAC controls a level of the bias current through the current source device based on the final trim code.

### BACKGROUND

Some integrated circuits (ICs) are “trimmed” prior to their use in a larger circuit. An operational amplifier, for example, has an internal bias current that may influence certain parameters of the operational amplifier such as power consumption, bandwidth, noise, and settling time. Some ICs that require trimming have relatively few pins. For example, an operational amplifier IC may only have five pins—two pins for the input signals to the amplifier, one pin for the output signal from the amplifier, and two positive power supply pins. Trimming an IC may require the inclusion of additional pins to support communication with an external circuit to determine suitable trim values for the IC. Providing additional pins on an IC can make the IC package undesirably large and expensive. Also, using an external circuit to trim an IC may take considerable time.

### SUMMARY

In one example, an integrated circuit (IC) includes a current source device configured to generate a bias current. The IC also includes a comparator, a circuit, a memory, and a digital-to-analog circuit (DAC). The comparator has a first input, a second input, and a comparator output. The first input receives a reference voltage, and the second input receives a voltage indicative of a bias current through the IC. The circuit is coupled to the comparator output. The circuit iteratively generates a final trim code based on an output signal from the comparator. The memory stores the final trim code. The DAC controls a level of the bias current through the current source device based on the final trim code.

In another example, a system includes a printed circuit board (PCB), a voltage supply node on the PCB, and a device coupled to the PCB and to the voltage supply node. The device includes a current source device configured to generate a bias current. The device further includes a comparator having a first input, a second input, and a comparator output. The first input receives a reference voltage and the second input receives a voltage indicative of a bias current through the integrated circuit. The device also includes a circuit coupled to the comparator output. The circuit iteratively generates a final trim code based on an output signal from the comparator. A memory stores the final trim code. A digital-to-analog circuit (DAC) controls a level of the bias current through the current source device based on the final trim code.

In yet another example, a method includes initializing a multi-bit trim code and iteratively determine a final trim code. Each iteration includes changing a bit of the multi-bit trim code from a first logic state to a second logic state, adjusting a bias current to produce an adjusted bias current, and, responsive to the adjusted bias current changing by more than a threshold amount, changing the bit back to the first logic state.

### BRIEF DESCRIPTION OF THE DRAWINGS

For a detailed description of various examples, reference will now be made to the accompanying drawings in which:

FIG. 1 illustrates a device capable of self-trimming its bias current.

FIG. 2 shows an example of the control of a bias current through an electrical circuit within the device of FIG. 1.

FIG. 3 illustrates a digital-to-analog converter (DAC) for use in trimming the bias current.

FIG. 4 includes a method for self-trimming bias current in an integrated circuit.

### DETAILED DESCRIPTION

The examples described herein pertain to an integrated circuit (IC) that includes “on-board” circuitry that generates a trim code usable to trim a bias current within the IC. The bias current, in turn, defines the total current consumption of the IC. In one example, the IC includes an electrical circuit such as an operational amplifier (OP AMP) that includes a trimmable bias current. It may be desirable to trim the bias current of the IC to a particular current value for a particular supply voltage (e.g., a bias current of 1 mA at a supply voltage of 5 V) to calibrate the bias current across process corners. Many conventional ICs require use of an external system to compute the trim code for the IC's bias current. Such ICs include a communication port that provides data from the IC to the external system for computation of the trim code, and that permits the external system to transmit the trim code to the IC for implementation thereon. The IC described herein, however, includes circuitry that itself determines the trim code. As such, an external system to generate the trim code is not needed, and thus a communication port for such purposes also is not needed.

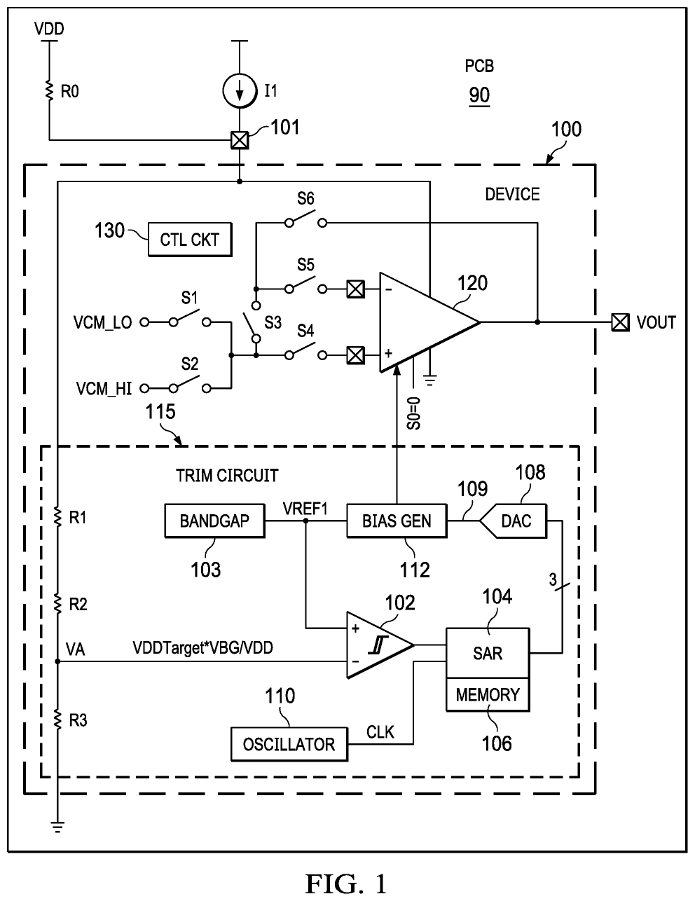

FIG. 1 illustrates a device 100 attached or otherwise coupled to a printed circuit board (PCB) 90. The device 100 in this example is an integrated circuit (IC) including one more operational amplifiers 120, although other types of electrical circuits are possible. The PCB 90 includes a resistor R0 and a current source device I1, which are attached to (for example, mounted on) the PCB 90, but are not part of the device 100 itself. One terminal of resistor R0 is coupled to a power supply voltage (VDD), and the resistor's other terminal is coupled to a voltage supply node 101 of device 100, when device 100 is present on the PCB 90. The current source device I1 also is connected to the voltage supply node 101.

The current source device I1 supplies a reference current (also referred to as I1) to the supply voltage node 101 of the device. The magnitude of I1 is the target bias current of the operational amplifier (op amp) 120. When the bias current through op amp 120 equals I1, no current flows through resistor R0, and thus the voltage on supply voltage node 101 equals VDD. If the bias current through op amp 120 is larger than I1, then current will from VDD, through resistor R0 into the supply voltage node 101, and into the op amp 120. As such, the voltage on the supply voltage node 101 will be less than VDD. Similarly, if the bias current through op amp 120 is smaller than I1, then current will from the supply voltage node 101, through resistor R0, and to the supply voltage VDD. As such, the voltage on the supply voltage node 101 will be greater than VDD. Thus, the bias current in op amp 120 is calibrated correctly to equal I1 when the voltage on the supply voltage node 101 equals VDD. Resistors R1, R2, and R2 are connected in series between the supply voltage node 101 and ground. Node VA is the node between resistors R2 and R3. Resistors R1-R3 comprise a voltage divider, and the voltage on node VA is a scaled down version of the voltage on the supply voltage node 101. The calibration circuitry of device 100 (described below) trims the bias current through op amp 100 by monitoring the voltage at node VA and comparing it to a fixed reference voltage.

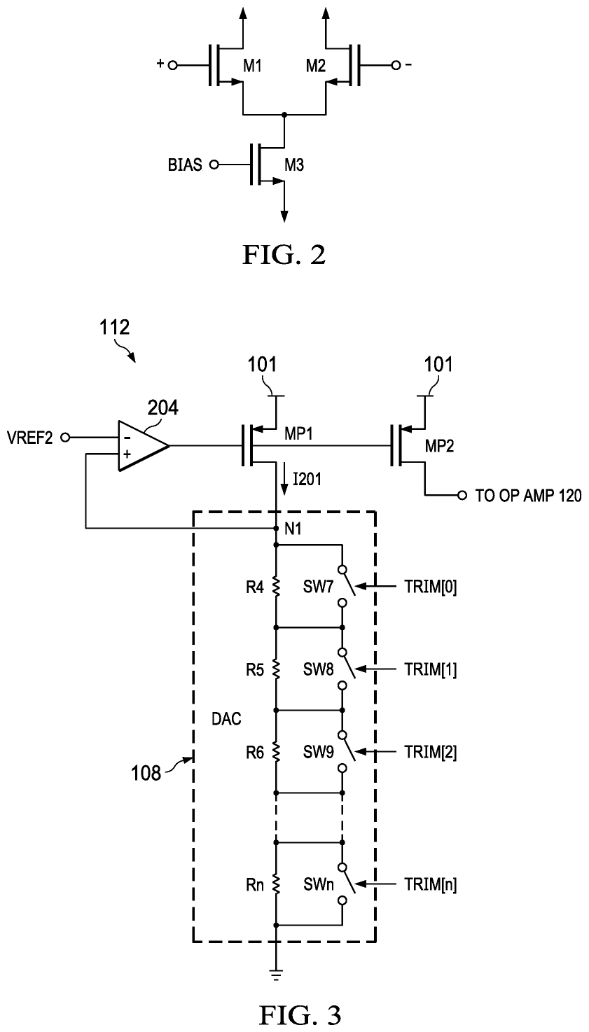

The bias current through op amp 120 may be, for example, the tail current through an input differential transistor pair. FIG. 2 shows an example of a portion of an input stage of an op amp comprising transistors M1, M2, and M3. In this example, transistors M1-M3 are n-type metal oxide semiconductor field effect transistors (NMOS transistors). The gate of transistor M1 is the positive (+) input of the op amp, and the gate of transistor M2 is the negative (−) input of the op amp. The sources of transistors M1 and M2 are coupled to the gate of tail current source transistor M3. The source of transistor M3 is connected to ground. The tail current through transistor M3 is a function, at least in part, of the gate-to-source voltage (Vgs) of transistor M3. Thus, by varying the gate voltage of transistor M3, the tail current through either or both of transistors M1 and M2 can be varied. The tail current through transistor M3 is the bias current in this example. In another example, the bias current is the current through a folded cascode circuit within an op amp. The bias current through op amp 120 is adjustable as explained below. The bias current influences device parameters such as power consumption, bandwidth, noise, and settling time.

In addition to the voltage divider comprising resistors R1-R3, device 100 also includes a voltage comparator 102, a bandgap reference source 103, a successive approximation register (SR) circuit 104, memory 106, a digital-to-analog converter (DAC) 108, an oscillator 110, a bias generator circuit 112, and switches S1-S6. The series resistance of resistors R1-R3 is substantially larger than that of the voltage supply connections through the op amp 120, and thus relatively little current from the supply voltage node 101 flows through resistors R1-R3. As explained above, R1-R3 form a voltage divider that divides down the voltage on the voltage supply node 101 to produce a divided-down voltage on the node VA between resistors R2 and R3. Thus, the voltage on VA is a function of the voltage on the voltage supply node 101 (e.g., VA=R3/(R1+R2+R3) times the voltage on supply voltage node 101).

The comparator 102 comprises a voltage comparator that compares the voltage on node VA to a reference voltage (VREF1) generated by the bandgap device 103. In the example of FIG. 1, VREF1 is coupled to the positive input of comparator 102, and node VA is coupled to the negative input of the comparator, although the polarity can be reversed from that shown in FIG. 1. The output of the comparator 102 indicates whether the VA node voltage is larger or smaller than VREF1. The comparator's output is coupled to an input of the SAR circuit 104, which is clocked by a clock signal (CLK) generated by oscillator 110. The SAR circuit 104 determines a suitable trim code to adjust the bias current through op amp 120. The SAR circuit 104 iteratively generates the trim code based on an output signal from the comparator 102. The trim code is iteratively determined with the resulting trim code referred to as the “final” trim code. The trim codes determined during the iterations are referred to as “interim” trim codes.

The final trim code is stored in memory 106, and then used to trim the bias current each time the device 100 operates (e.g., during a power cycle of device 100). Memory 106 may comprise a non-volatile storage device such as a read-only memory (ROM). In one example, the memory 106 comprises a one-time programmable ROM. Other types of non-volatile storage can be used as well for memory 106. The trim code comprises a multibit digital value. The trim code—interim or final—is converted from a digital value to an analog signal by DAC 108, and the analog signal 109 from the DAC 108 is provided to the bias generator 112. The bias generator 112 generates a control signal to the op amp 120 to control the level of bias current. In one example, the bias generator 112 controls the gate voltage on a transistor, such as transistor M3 in FIG. 2.

The components used to trim the bias current include the comparator 102, the bandgap device 103, the SAR circuit 104, memory 106, the DAC 108, the oscillator 110, and resistors R1-R3, and some, or all, of these components comprise a trim circuit 115 provided on device 100. Those components are provided as part of the same integrated circuit that includes the circuitry comprising the functional components of the device 100 (e.g., op amp 120). As the device 100 essentially can trim itself, a communication port is not needed (and not included) to communicate signals and data between the device 100 and external equipment. The lack of a communication port for trim purposes decreases the need for extra pins on device 100, which is particularly beneficial for amps or other relatively low pin-count ICs.

FIG. 3 shows an example of bias generator 112. In this example, bias generator 112 includes DAC 108. In the example of FIG. 2, transistor M3 controls the bias current through the op amp's input stage. Transistor M3 in FIG. 2 may comprise transistor MP2 in FIG. 3. The DAC 108 of the example of FIG. 1 includes a voltage reference (VREF2), an amplifier 204, a transistor MP1, resistors R4, R5, R6, . . . , Rn, and switches SW7, SW8, SW9, . . . , SWn. In this example MP1 and MP2 comprise p-type metal oxide semiconductor field effect transistors (PMOS transistors), although other types of transistors can be used as well (e.g., n-type metal oxide semiconductor field effect transistors (nMOS devices), bipolar junction transistors, etc.). Transistors have a control input and a pair of current terminals. In the case of PMOS transistors, MP1 and MP2 each have a gate, a drain, and a source. The sources of MP1 and MP2 are coupled together and to the voltage supply node 101. The gates of MP1 are coupled together and to the output of the amplifier 204. In one example, the tail current source device M3 in FIG. 2 can be implemented as a PMOS transistor, such as MP2 in FIG. 3.

The drain of MP1 is coupled to the series-coupled chain of resistors R4 through Rn, with Rn being coupled to ground. Two or more resistors are included in the series chain, and thus “n” is 2 or larger. A switch is coupled across each resistor. Switch SW7 is coupled across resistor R4. Switch SW8 is coupled across resistor R5, and so on. The node N1 connecting the drain of MP1 to resistor R4 is connected to one input (e.g., positive) of amplifier 204. VREF2 is coupled to the other input (e.g., negative) of amplifier 204.

Each bit of the trim code controls the on/off state of a corresponding switch SW7-SWn. For example, bit zero of the trim code (TRIM[0]) controls SW7. Similarly, TRIM[1], TRIM[2] and TRIM[n] controls SW8, SW9, and SWn, respectively. In an example of a 5-bit trim code, there will be five resistors in the series chain between the drain of MP1 and ground, and five corresponding switches, and each of the 5 trim code bits controls one of the five switches. In one example, each of the resistors R4-Rn have the same resistance value, but in other examples, the resistors may be binary-weighted (or weighted in some other fashion). As a binary-weighted set of resistors, one resistance may have a unit resistance, another has two times the unit resistance, another has four times the unit resistance, and so on.

Current I201 flows through MP1 and the series chain of resistors R4-Rn, thereby creating a voltage across the series chain of resistors on node N1. Depending on which switch(es) SW7-SWn are closed (which itself depends on the logic levels of the trim code bits), a particular voltage will be provided to the positive input of amplifier 204. The difference between that voltage and VREF2 is amplified by amplifier 204, and the amplifier's output voltage is provided to gates of MP1 and MP2. The sources of MP1 and MP2 are fixed at the voltage of node 101. The amplifier's output voltage controls the gate-to-source voltage (VGS) of MP1 and MP2, and thus the magnitude of the current through MP1 and MP2. In one implementation, the magnitude of VREF2 and VREF2 is the same, but can be different in other implementations.

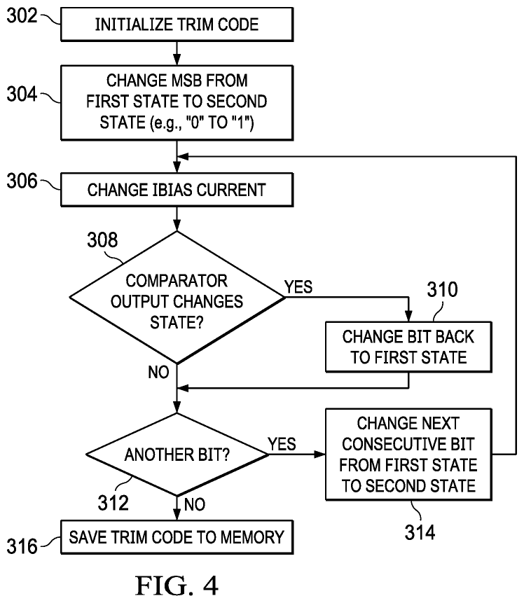

The operation of device 100 to trim its own bias current will now be described. It may be desired to trim the bias current to a certain level for a particular supply voltage. For example, it may be desired to trim to 50 microamperes for a VDD of 5V. FIG. 4 illustrates the iterative process implemented by device 100 to self-trim its bias current. At 302, the trim code is initialized to a predetermined value. In one example, the initial state of the trim code is [000 . . . 0].

Then, at 304, the state of the most significant bit (MSB) of the trim code is changed from a first state to a second state. In the example in which the trim code is initialized to [000 . . . 0], the MSB is changed from a 0 to a 1 to produce an interim trim code of [100 . . . 0]. At 306, the bias current is changed based on the new interim trim code. This operation is performed by the bits of the interim trim code controlling the on/off states of switches SW7-SWn, which then provides a different voltage input to the positive input of amplifier 204. As a result, the VGS of both MP1 and MP2 is changed, which causes a corresponding change in both current I201 and IBIAS. MP1 and MP2 may be of the same size (i.e., same channel width (W) and same channel length (L)), or MP1 may have a smaller W/L ratio than MP2. I201 is a function (either equal to or smaller than) IBIAS, but is proportional to IBIAS.

The change in bias current through the op amp 120 also causes the voltage on supply voltage node 101 to change, as well as on node VA. At 308, the output of comparator 102 is monitored by the SAR circuit 104. The comparator output is initially at a predetermined value. With the trim code initialized to [000 . . . 0], the initial magnitude of the bias current will be smaller than its final trim value, and thus the voltage on the supply voltage node 101 will be larger than VDD, and the VA node is also will be larger than VREF1. With the change in the bias current to a larger level, the new voltage on the VA node may be decrease. VREF1 is a reference voltage that represents the voltage on the VA node when IBIAS is properly trimmed.

At 308, the successive approximation circuit 104 determines whether the output of comparator 102 changes state. If the comparator's output changes state (e.g., from 0 to 1), then that means that bias current is now too large, and at 310, the previously changed bit (e.g., the MSB changed in operation 304) is changed back to its first state (e.g., from 1 back to 0). Otherwise, the bit is left as-is. In either case, at 312, it is determined whether another bit exists in the interim trim code to be assessed. For example, if the trim code has 5 bits [4:0], once bit [4] (MSB) is determined, then bit [3] is next assessed. Then, bit [2], and so on. If another in the interim code remains to be assessed, then at 314, that bit is changed from its initialized state to the opposite state (e.g., from 0 to 1), and the bias current is again changed as explained above.

As such, each trim code bit beginning with the MSB is toggled from its initialized state to the other logic state, and whether the bias current is too small or too large (e.g., by comparing the VA node voltage to VREF1) is determined for each interim trim code. Each toggled bit of the interim code is reverted back to its initialized state if the change to the bias current a given iteration is too large; otherwise, the toggled trim code bit is left in its new (toggled) state. Once all of the bits of the trim code are determined, the final trim code is then saved to memory 106 (316), and the final trim code is used to trim the switches SW-SWn each time the device 100 is powered on.

Referring again to FIG. 1, the on/off states of switches S1-S6 are controlled by control circuit 130. The switches S1-S6 are configured by control signals generated by control circuit 130 to configure the op amp 120 into a desired configuration when trimming its bias current. For example, switch S1 and S4-S6 (but not S2) may be turned on (closed) to couple a lower common mode voltage (VCM_LO) to both the + and − inputs of the op amp 120. Alternatively, S2-S6 are turned on (and not S1) to couple a higher common mode voltage (VCM_HI) to both the + and − inputs of the op amp 120. Leaving the + and − inputs floating can detrimentally impact the proper determination of the bias current.

In this description, the term “couple” or “couples” means either an indirect or direct wired or wireless connection. Thus, if a first device couples to a second device, that connection may be through a direct connection or through an indirect connection via other devices and connections. Modifications are possible in the described embodiments, and other embodiments are possible, within the scope of the claims.

1. An integrated circuit, comprising:
an electrical circuit having a bias terminal configured to receive a bias current from a current generator;
a comparator having a first input, a second input, and a comparator output, the first input coupled to a bandgap reference source and the second input coupled to receive a voltage indicative of the bias current;
a successive approximation register (SAR) circuit having an input coupled to the comparator output, the SAR circuit configured to provide at a SAR output a final trim code based on an output signal from the comparator;
a memory coupled to the SAR output, the memory configured to store the final trim code;
a digital-to-analog circuit (DAC) having an input coupled to the SAR output and having an output; and
a bias generator circuit having an input coupled to the output of the DAC and an output coupled to the electrical circuit, and configured to provide a control signal at an output of the bias generator to control the bias current.

2. The integrated circuit of claim 1, wherein prior to providing the final trim code, the SAR circuit iteratively provides at least one interim trim code, and wherein, in each iteration, the SAR circuit is configured to change a logic state of one bit within a respective interim trim code.

3. The integrated circuit of claim 2, wherein, within each iteration, the SAR circuit is configured to change the logic state of the most significant bit (MSB) first.

4. The integrated circuit of claim 1, wherein the final trim code is a multibit value, and wherein the SAR circuit is configured to:
initialize a trim code to an initial value;
change a logic state of the most significant bit of the initial value from a first logic state to a second logic state;
determine a logic state of the comparator's output signal; and
change the logic state of the most significant bit back to the first logic state responsive to a change in the logic state of the comparator's output signal.

5. The integrated circuit of claim 4, wherein the SAR circuit is configured to:
iteratively change a logic state of each successive bit of the trim code from the most significant bit to the least significant bit to generate the final trim code; one respective bit of the trim code changing state within each iteration and
with each iteration, responsive to the comparator's output signal changing state, change back the logic state of the respective bit.

6. The integrated circuit of claim 1, including an amplifier having a control terminal coupled to the bias generator output, and wherein the DAC includes a series chain of resistors.

7. The integrated circuit of claim 6, further including a first transistor having a current terminal coupled to the series chain of resistors.

8. The integrated circuit of claim 7, including further comprising a second transistor, and wherein:
the first transistor having a first control input and a current terminal;
the second transistor having a second control input coupled to the first control input and to an output of the amplifier;
and
the amplifier includes a first amplifier input configured to receive a reference voltage and a second amplifier input coupled to the series chain of resistors and the current terminal of the first transistor.

9. The integrated circuit of claim 1, wherein the electrical circuit includes an operational amplifier.

10. A system, comprising:
a printed circuit board (PCB);
a voltage supply node on the PCB;
a device coupled to the PCB and to the voltage supply node, the device including:
an electrical circuit having a bias terminal configured to receive a bias current from a current generator;
a comparator having a first input, a second input, and a comparator output, the first input coupled to a bandgap reference source and the second input coupled to receive a voltage indicative of the bias current;
a successive approximation register (SAR) circuit having an input coupled to the comparator output, the SAR circuit configured to provide at a SAR output a final trim code based on an output signal from the comparator;
a memory coupled to the SAR output, the memory configured to store the final trim code;
a digital-to-analog circuit (DAC) having an input coupled to the SAR output, and having an output; and
a bias generator circuit having an input coupled to the output of the DAC and an output coupled to the electrical circuit, and configured to provide a control signal at an output of the bias generator to control the bias current.

11. The system of claim 10, wherein:
prior to providing the final trim code, the SAR circuit iteratively provides at least one interim trim code;
in each iteration, the SAR circuit is configured to change a logic state of one bit within a respective interim trim code; and
in each iteration, the DAC is configured to change the level of the bias current through the electrical circuit.

12. The system of claim 10, wherein the final trim code is a multibit value, and wherein the SAR circuit is configured to:
initialize a trim code to an initial value;
change a logic state of the most significant bit of the initial value from a first logic state to a second logic state;
determine a logic state of the comparator's output signal; and
change the logic state of the most significant bit back to the first logic state responsive to a change in the logic state of the comparator's output signal.

13. The system of claim 12, wherein the SAR circuit is configured to:
iteratively change a logic state of each successive bit of the trim code from the most significant bit to the least significant bit to generate the final trim code; one respective bit of the trim code changing state within each iteration and
with each iteration, responsive to the comparator's output signal changing state, change back the logic state of the respective bit.

14. The system of claim 10, including an amplifier having first and second amplifier inputs and an output, and wherein the DAC comprises a series chain of resistors and a plurality of switches, each switch being coupled in parallel with a respective one of the resistors, and a first resistor in the series chain being coupled to the first amplifier input.

15. The system of claim 14, further including a first transistor having a first control input and having a current terminal coupled to the first resistor in the series chain of resistors, wherein when a current flows through the transistor, the current also flows through the chain of resistors.

16. The system of claim 15, further including a second transistor wherein:
the second transistor includes a second control input coupled to the first control input and to the output of the amplifier;
and
the second input of the amplifier is configured to receive a reference voltage.

17. The system of claim 10, further including a resistor mounted on the PCB and coupled between the voltage supply node and the device.

18. A method, comprising:
initializing a multi-bit trim code; and
iteratively determining a final trim code, each iteration including:
changing a bit of the multi-bit trim code from a first logic state to a second logic state;
adjusting a bias current to produce an adjusted bias current; and
responsive to the adjusted bias current changing by more than a threshold amount, changing the bit back to the first logic state.

19. The method of claim 18, wherein iteratively determining the final trim code comprises changing each bit of the multi-bit trim code starting with the most significant bit and ending with the least significant bit of the multi-bit trim code.

20. The method of claim 18, further including storing the trim code in a non-volatile memory.
